(19) United States
(12) Patent Application Publication
(10) Pub. No.: US 2009/0001596 A1
(43) Pub. Date: Jan. 1, 2009

(54) CONDUCTIVE LINE STRUCTURE

(75) Inventors: Chin-Lung Lin, Hsinchu City (TW); Yun-Sheng Huang, Taipei County (TW); Hung-Chin Thuang, Kaohsiung City (TW); Chien-Fu Lee, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: UNITED MICROELECTRONICS CORP., Hsinchu (TW)

(21) Appl. No.: 12/211,079

(22) Filed: Sep. 15, 2008

Related U.S. Application Data
(62) Division of application No. 11/306,168, filed on Dec. 19, 2005.

(51) Int. Cl. H01L 23/48

(52) U.S. Cl. 257/776; 257/E23.01

(57) ABSTRACT

A conductive line structure is defined with an OPC photomask and is suitably applied to a semiconductor device. The conductive line structure includes a first conductive line and a second conductive line. The first conductive line includes a first line body oriented in the X-direction of a plane coordinate system, a first end portion at one end of the first line body slanting toward the Y-direction of the plane coordinate system, and a second end portion at the other end of the first line body also slanting toward the Y-direction. The second conductive line arranged in an end-to-end manner with the first conductive line includes a second line body oriented in the X-direction, a third end portion at one end of the second line body slanting toward the Y-direction, and a fourth end portion at the other end of the second line body also slanting toward the Y-direction.

### CROSS-REFERENCE TO RELATED APPLICATION

This application is a divisional of an application Ser. No. 11/306,168, filed on Dec. 19, 2005, now pending. The entirety of each of the above-mentioned patent applications is hereby incorporated by reference herein and made a part of this specification.

### BACKGROUND OF THE INVENTION

1. Field of the Invention

The present invention relates to an optical proximity correction (OPC) method, an OPC photomask and a conductive line structure. More particularly, the present invention relates to an OPC method capable of improving the process window of a lithography process, an OPC photomask made based on the OPC method, and a conductive line structure obtained with the OPC photomask.

2. Description of the Related Art

Because the integration degree of integrated circuit is always required higher, the dimensions of various electronic devices are reduced unceasingly. In a semiconductor process, the key step for the dimension reduction should be the lithography steps.

The linewidth reduction in other semiconductor processes is also dependent on development of the lithography technology. Since the accuracy of pattern transfer in lithography greatly affects the yield, many methods capable of improving the photomask factor in lithographic resolution have been developed, including various OPC methods.

However, when the distance between the two ends of two adjacent line patterns arranged in an end-to-end manner is overly small, mis-connection between line patterns easily occurs if a conventional OPC method is utilized. Therefore, a new OPC method is highly required for further improving the photomask factor in lithographic resolution and improving the process window of the lithography process.

### SUMMARY OF THE INVENTION

In view of the foregoing, this invention provides an OPC method capable of preventing mis-connection between two line patterns in an end-to-end arrangement.

This invention also provides an OPC photomask, which is fabricated based on the OPC method of this invention.

This invention further provides a conductive line structure, which is formed by using the OPC photomask of this invention so that short circuit between adjacent conductive lines can be prevented effectively and the process window can be increased.

The OPC method of this invention is described below. A photomask pattern that includes multiple line patterns arranged in an end-to-end manner is provided, wherein each line pattern is oriented in the X-direction of a plane coordinate system and has a width of “W” in the Y-direction of the plane coordinate system. An initial correction step is conducted to add an end pattern at each of the two ends of each line pattern, wherein the end pattern includes a first pattern and a second pattern. The first pattern directly connects with the end of the line pattern, has a maximal width of “W1” in the Y-direction, and has a maximal length of “L1” in the X-direction as measured from the end of the line pattern. The second pattern directly connects with the end of the line pattern and the first pattern, has a maximal width of “W2” in the Y-direction, and has a maximal length of “L2” in the X-direction as measured from the end of the line pattern, while the inequalities of “W1+W2>W” and “L1>L2” are satisfied. Then, a fine correction step is conducted to correct the line patterns and the end patterns.

In the above method of this invention, the two end patterns between two adjacent line patterns are in a mirror-symmetric or point-symmetric arrangement. The fine correction step may include a step of correcting the line edges of the line patterns and the edges of the end patterns.

The OPC photomask of this invention is made based on a substrate according to the correction result of the above OPC method of this invention. Hence, the patterns on the OPC photomask are the same as those mentioned above.

The conductive line structure of this invention is defined with an above-mentioned OPC photomask and is suitably applied to a semiconductor device, including a first conductive line and a second conductive line. The first conductive line includes a first line body oriented in the X-direction of a plane coordinate system, a first end portion at one end of the first line body slanting toward the Y-direction of the plane coordinate system, and a second end portion at the other end of the first line body also slanting toward the Y-direction. The second conductive line is arranged in an end-to-end manner with the first conductive line, and includes a second line body oriented in the X-direction, a third end portion at one end of the second line body slanting toward the Y-direction, and a fourth end portion at the other end of the second line body also slanting toward the Y-direction, wherein the third end portion is adjacent to the second end portion.

Moreover, each of the first to fourth end portions may slant toward positive or negative Y-direction. Therefore, the following combinations are possible: (1p, 2p, 3n, 4n), (1p, 2p, 3p, 4p), (1p, 2n, 3p, 4n), (1p, 2n, 3n, 4p), (1p, 2p, 3n, 4p) and (1p, 2p, 3p, 4n), wherein the numerals 1-4 represent the first to fourth end portions in sequence, and “p” and “n” represent the positive Y-direction and the negative Y-direction, respectively, toward which the end portion slants. The material of the first and the second conductive lines may be a metal, such as, copper (Cu), aluminum (Al) or tungsten (W). In addition, the first and second conductive lines may include doped polysilicon, and the semiconductor device to which the conductive line structure is applied may be a static random access memory (SRAM) device.

Since the OPC method of this invention corrects the end portions of line patterns to an asymmetric shape, the end portions of the defined line patterns slant toward the perpendicular direction when an OPC photomask made based on the OPC method is used in the lithography process. Therefore, mis-connection between adjacent line patterns can be effectively prevented, and the process window can be increased. Moreover, when the defined line patterns are conductive lines, short circuit between adjacent conductive lines can be avoided because mis-connection between them can be prevented effectively.

It is to be understood that both the foregoing general description and the following detailed description are exemplary, and are intended to provide further explanation of the invention as claimed.

### BRIEF DESCRIPTION OF THE DRAWINGS

FIGS. 1A, 1B and 1D illustrate the steps of an OPC method according to an embodiment of this invention, and FIG. 1C shows the arrangement of the end patterns in another embodiment of this invention.

FIGS. 2 and 3 illustrate the OPC photomasks according to an embodiment and another embodiment, respectively, of this invention.

FIGS. 4-9 illustrate the conductive line structures according to different embodiments of this invention.

### DESCRIPTION OF THE PREFERRED EMBODIMENTS

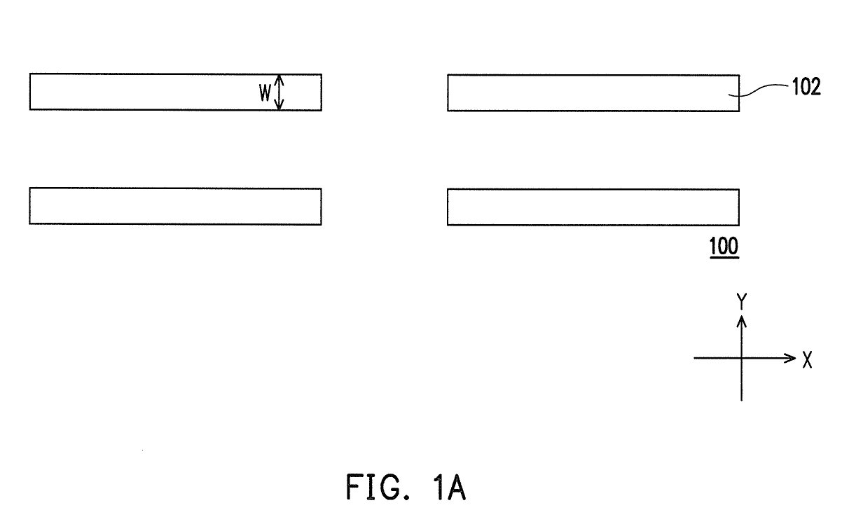

FIGS. 1A, 1B and 1D illustrate the steps of an OPC method according to an embodiment of this invention, and FIG. 1C shows the arrangement of the end patterns in another embodiment of this invention.

Referring to FIG. 1A, a photomask pattern 100 that includes multiple line patterns 102 arranged in an end-to-end manner is provided, wherein each line pattern 102 is oriented in the X-direction of a plane coordinate system and has a width of “W” in the Y-direction of the plane coordinate system.

Referring to FIG. 1B, an initial correction step is conducted to add an end pattern 104 at each of the two ends of each line pattern 102, wherein the end pattern 104 includes a first pattern 104a and a second pattern 104b. The first pattern 104a directly connects with the corresponding end of the corresponding line pattern 102, has a maximal width of “W1” in the Y-direction, and has a maximal length of “L1” in the X-direction as measured from the end of the line pattern 102.

The second pattern 104b directly connects with the end of the line pattern 102 and the first pattern 104a, has a maximal width of “W2” in the Y-direction, and has a maximal length of “L2” in the X-direction as measured from the end of the line pattern 102, while the inequalities of “W1+W2>W” and “L1>L2” are satisfied.

In this embodiment, the two end patterns 104 between two adjacent line patterns 102 are in a point-symmetric arrangement, which means that one end pattern 104 will superimposes the other after being rotated by 180° and translated in the X-direction. However, as shown in FIG. 1C, in another embodiment of this invention, the two end patterns 106 each including a first pattern 106a and a second pattern 106b between two adjacent line patterns 102 are in a mirror-symmetric arrangement with a Y-directional line 108 between the two end patterns 106 as a mirror line.

Though in the above embodiments the end pattern 104/106 includes the first pattern 104a/106a and the second pattern 104b/106b both in rectangular shape, the end patterns suitably used in this invention are not restricted to this. The end pattern may alternatively be an asymmetric serif pattern, an asymmetric hammer-head pattern, an asymmetric jog pattern or any combination thereof. It is noted that symmetric serif, hammer-head and jog patterns are often used in conventional OPC methods.

Referring to FIG. 1D, a fine correction step is conducted, possibly using an ordinary OPC computer program, to correct the line patterns 102 and the end patterns 104, especially the line edges of the line patterns 102 and the edges of the end patterns 104, to obtain corrected line patterns 102′ and end patterns 104′.

The OPC photomasks fabricated based on the OPC method of this invention will be described as follows.

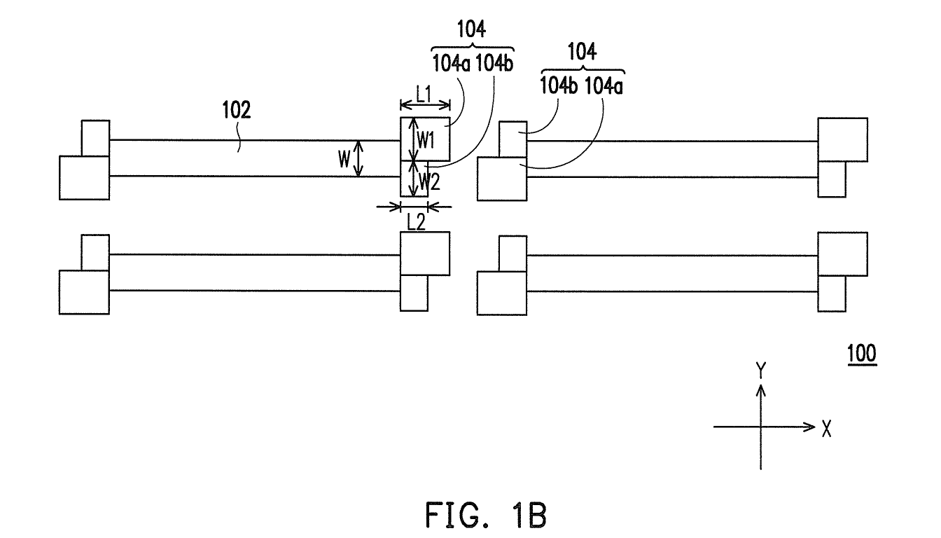

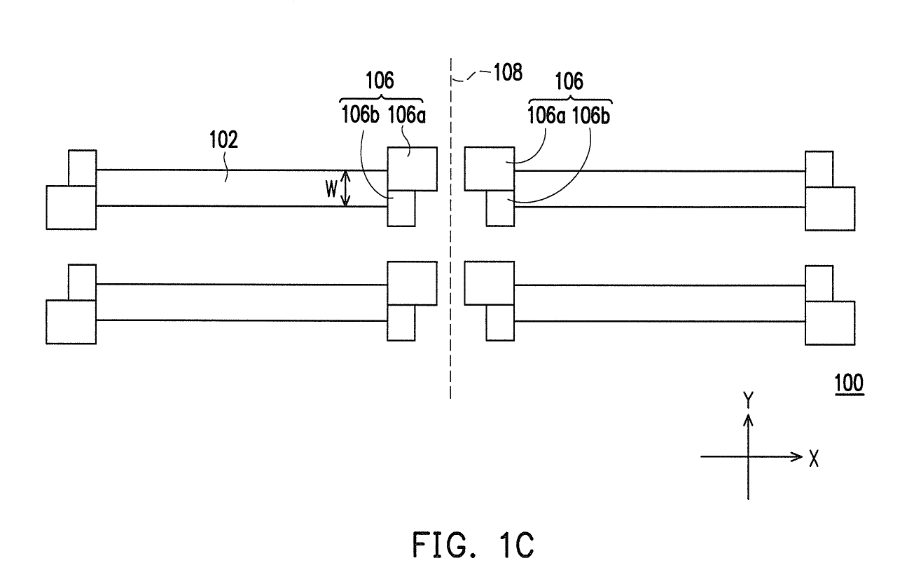

FIGS. 2 and 3 illustrate the OPC photomasks according to an embodiment and another embodiment, respectively, of this invention.

Referring to FIG. 2, the OPC photomask includes a substrate 200 and line patterns 202 and end patterns 204 thereon, wherein the line patterns 202 and the end patterns 204 constitute a photomask pattern for defining patterns in a lithography process. The material of the substrate 200 may be transparent glass, for example.

The line patterns 202 are arranged in an end-to-end manner on the substrate 200, wherein each line pattern 202 is oriented in the X-direction of a plane coordinate system and has a width of “W” in the Y-direction of the plane coordinate system.

An end pattern 204 is disposed at each of the two ends of each line pattern 202, including a first pattern 204a and a second pattern 204b. The first pattern 204a directly connects with the corresponding end of the corresponding line pattern 202, has a maximal width of “W1” in the Y-direction, and has a maximal length of “L1” in the X-direction as measured from the end of the line pattern 202. The second pattern 204b directly connects with the end of the line pattern 202 and the first pattern 204a, has a maximal width of “W2” in the Y-direction, and has a maximal length of “L2” in the X-direction as measured from the end of the line pattern 202, while the inequalities of “W1+W2>W” and “L1>L2” are satisfied.

In this embodiment, the two end patterns 204 between two adjacent line patterns 202 are in a point-symmetric arrangement, which means that one end pattern 204 will superimposes the other after being rotated by 180° and translated in the X-direction. However, as shown in FIG. 3, in another embodiment of this invention, the two end patterns 206 each including a first pattern 206a and a second pattern 206b between two adjacent line patterns 202 are in a mirror-symmetric arrangement with a Y-directional line 208 between the two end patterns 206 as a mirror line.

In addition, the line patterns 202 and the end patterns 204 and 206 may be opaque patterns, of which the material may be chromium, or transparent patterns, depending on the type (positive- or negative-type) of the photoresist material used. This will not be further explained as being well known by one skilled in the art.

Since the end pattern 204 at an end of each line pattern 202 on the above OPC photomask is an asymmetric pattern, the end portions of each line pattern defined by the photomask in a lithography process slant in the perpendicular direction (Y-direction). Therefore, mis-connection between adjacent line patterns can be effectively prevented, and the process window can be increased.

Some embodiments of the conductive line structure defined with the OPC photomask of this invention are described below.

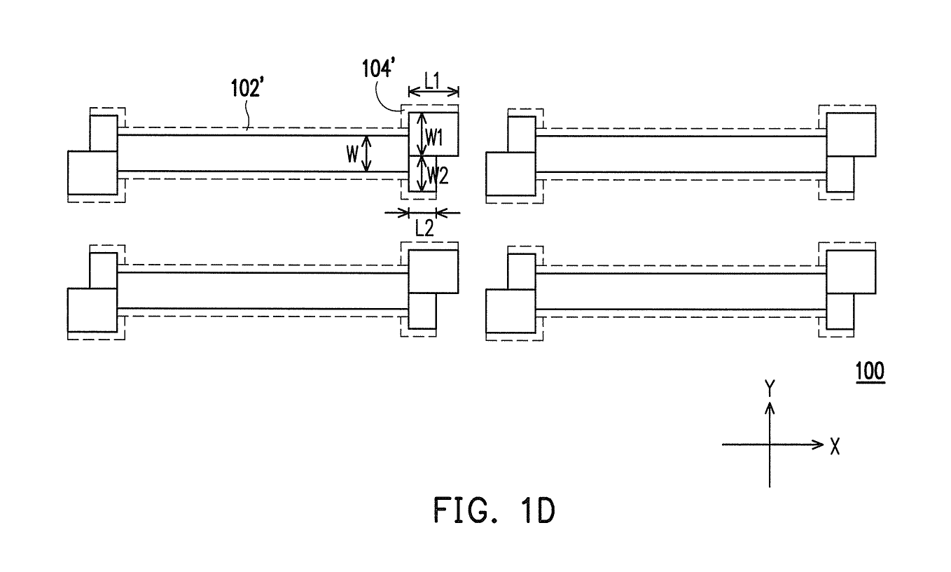

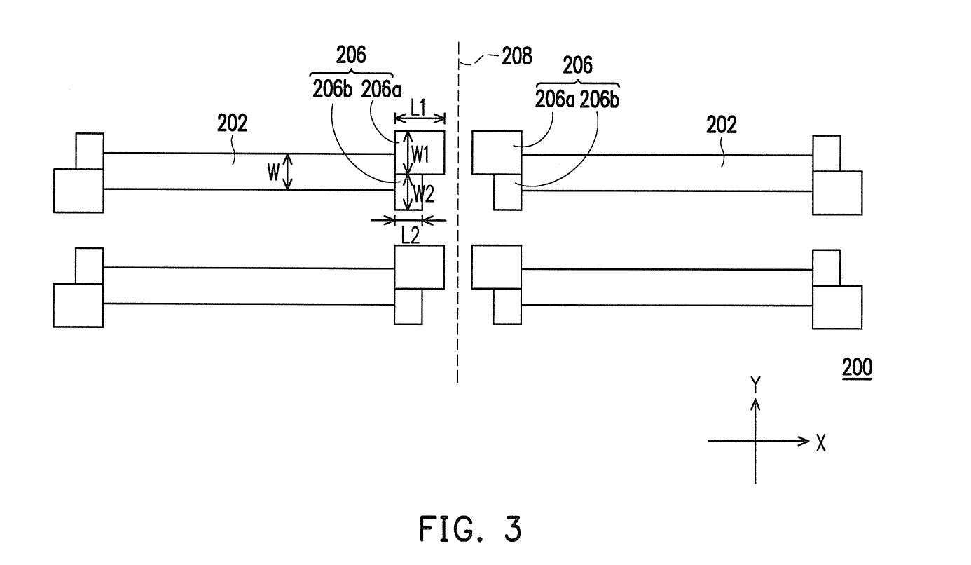

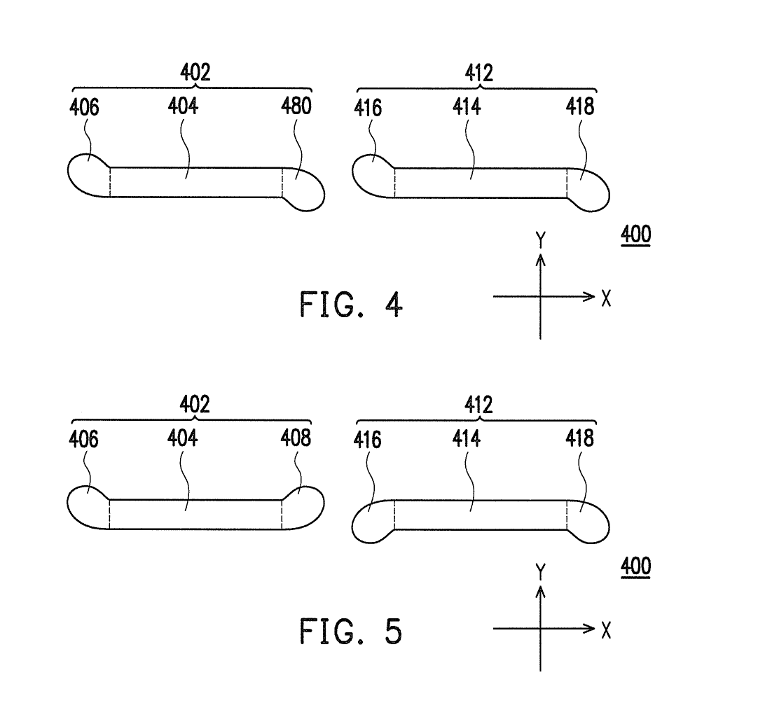

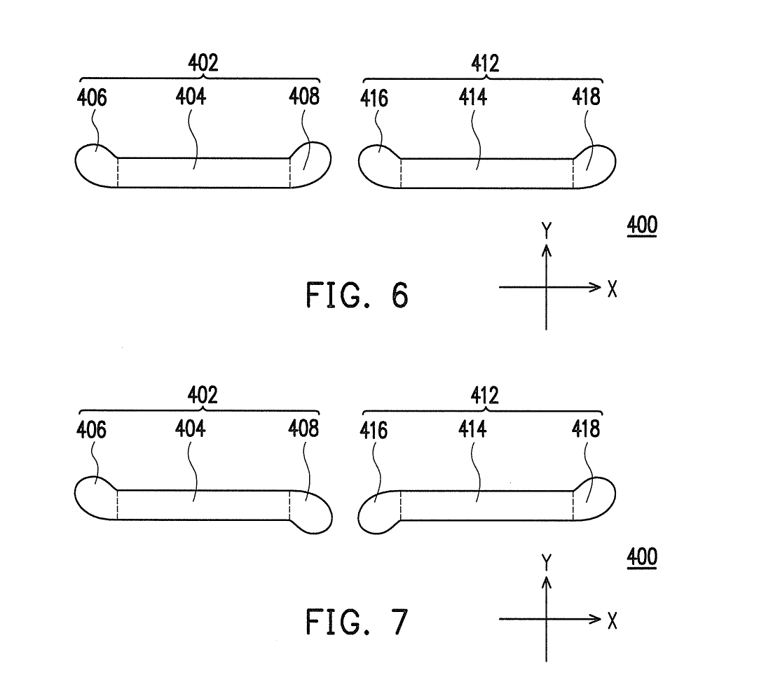

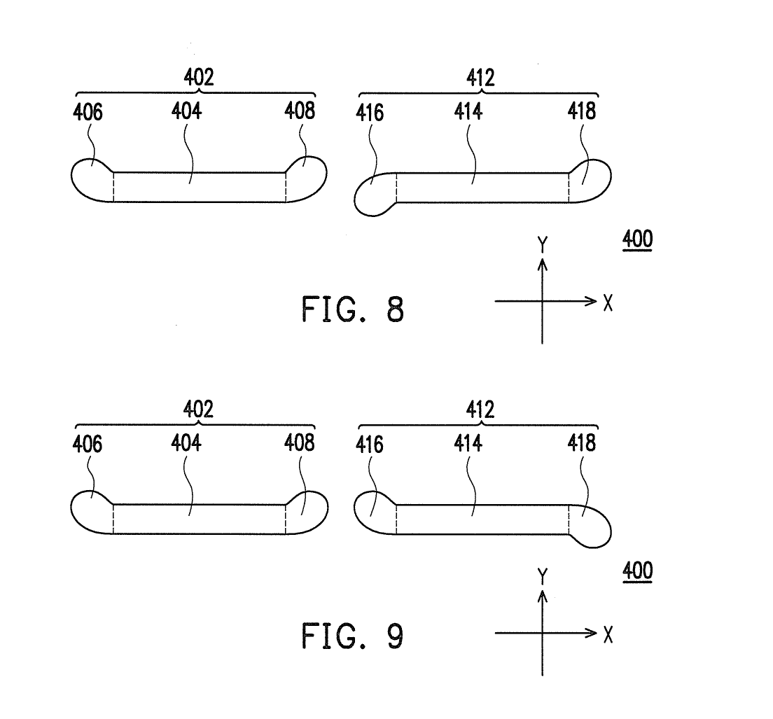

FIGS. 4-9 illustrate the conductive line structures according to different embodiments of this invention.

Referring to FIG. 4, the conductive line structure of each embodiment of this invention is suitably applied to a semiconductor device like an SRAM device, in which the gate layers of the MOS transistors as basic elements of the SRAM device are formed as several short conductive lines arranged in an end-to-end manner. The conductive line structure includes a first conductive line 402 and a second conductive line 412 disposed on a semiconductor substrate 400, wherein the first conductive line 402 and the second conductive line 412 may include doped polysilicon, or a metal like copper, aluminum or tungsten, for example.

The first conductive line 402 includes a first line body 404 oriented in the X-direction of a plane coordinate system, a first end portion 406 at one end of the first line body 404 slanting toward a Y-direction (e.g., the positive Y-direction) of the plane coordinate system, and a second end portion 408 at the other end of the first line body 404 slanting toward a Y-direction (e.g., the negative Y-direction).

The second conductive line 412 is arranged in an end-to-end manner with the first conductive line 402, and includes a second line body 414 oriented in the X-direction, a third end portion 416 at one end of the second line body 414 slanting toward a Y-direction (e.g., the positive Y-direction), and a fourth end portion 418 at the other end of the second line body 414 slanting toward a Y-direction (e.g., the negative Y-direction), wherein the third end portion 416 is adjacent to the second one 408.

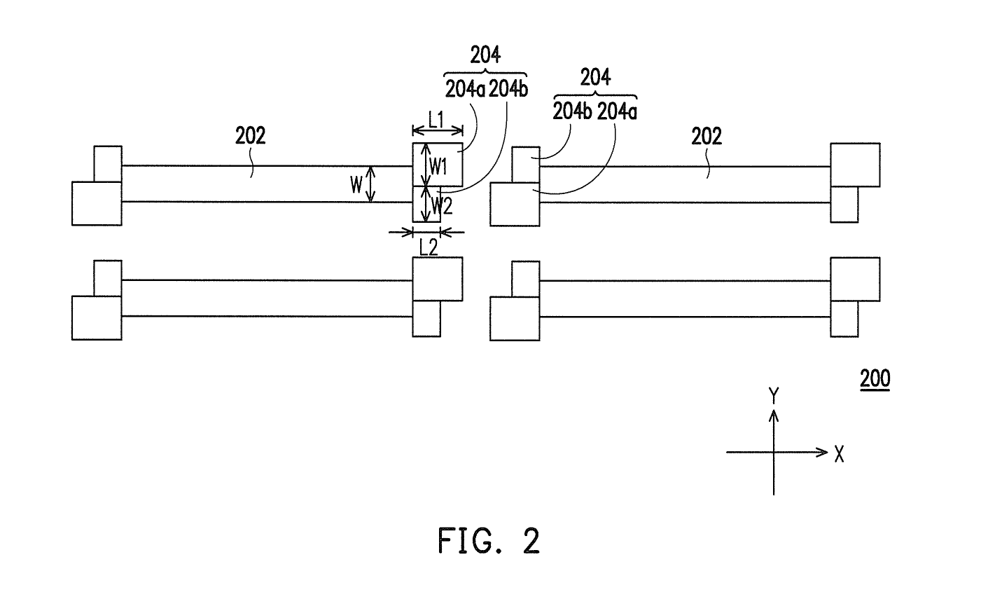

Since any end portion of the first and second conductive lines 402 and 412 may slant toward the positive Y-direction or the negative Y-direction, there are several other combinations for the slanting directions of the four end portions 406, 408, 416 and 418 except that in FIG. 4. The combinations of (1p, 2p, 3n, 4n), (1p, 2p, 3p, 4p), (1p, 2n, 3n, 4p), (1p, 2p, 3n, 4p) and (1p, 2p, 3p, 4n) are illustrated in FIGS. 5-9 in sequence, wherein the numerals 1-4 represent the first to fourth end portions in sequence and “p” and “n” represent the positive Y-direction and the negative Y-direction, respectively, toward which the end portion slants.

Moreover, the conductive line structure in each of FIGS. 4-9 can be applied to a dense line structure, which may be constituted of many of the conductive line structure as a repetition unit that are arranged in parallel.

Since the end portions of the conductive line patterns are formed slanting toward the perpendicular direction, mis-connection between them can be prevented effectively so that short circuit between adjacent lines can be avoided.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A conductive line structure applied to a semiconductor device, comprising:
a first conductive line, comprising:
a first line body oriented in an X-direction of a plane coordinate system;
a first end portion at one end of the first line body, slanting toward a Y-direction of the plane coordinate system; and
a second end portion at the other end of the first line body, slanting toward a Y-direction; and
a second conductive line, arranged in an end-to-end manner with the first conductive line, and comprising:
a second line body oriented in the X-direction;
a third end portion at one end of the second line body, slanting toward a Y-direction; and
a fourth end portion at the other end of the second line body, slanting toward a Y-direction, wherein the second end portion is adjacent to the third end portion.

2. The conductive line structure of claim 1, wherein the first and the second end portions slant toward a positive Y-direction, but the third and the fourth end portions slant toward a negative Y-direction.

3. The conductive line structure of claim 1, wherein the first and the second end portions slant toward a positive Y-direction, and the third and the fourth end portions also slant toward the positive Y-direction.

4. The conductive line structure of claim 1, wherein the first and the third end portions slant toward a positive Y-direction, but the second and the fourth end portions slant toward a negative Y-direction.

5. The conductive line structure of claim 1, wherein the first and the fourth end portions slant toward a positive Y-direction, but the second and the third end portions slant toward a negative Y-direction.

6. The conductive line structure of claim 1, wherein the first, the second and the fourth end portions slant toward a positive Y-direction, but the third end portion slants toward a negative Y-direction.

7. The conductive line structure of claim 1, wherein the first to third end portions slant toward a positive Y-direction, but the fourth end portion slants toward a negative Y-direction.

8. The conductive line structure of claim 1, wherein the first and the second conductive lines comprise doped polysilicon.

9. The conductive line structure of claim 1, wherein the first and the second conductive lines comprise a metal.

10. The conductive line structure of claim 9, wherein the metal is copper (Cu), aluminum (Al) or tungsten (W).

11. The conductive line structure of claim 1, wherein the semiconductor device comprises a static random access memory (SRAM) device.
